(19) United States
(12) Patent Application Publication
(10) Pub. No.: US 2026/0164670 A1
(43) Pub. Date: Jun. 11, 2026

(54) SEMICONDUCTOR DEVICE AND METHOD FOR FABRICATING THE SAME

(71) Applicant: SK hynix Inc., Gyeonggi-do (KR)

(72) Inventor: Cha Deok DONG, Gyeonggi-do (KR)

(21) Appl. No.: 19/242,976

(22) Filed: Jun. 19, 2025

(30) Foreign Application Priority Data
Dec. 10, 2024 (KR) 10-2024-0182369

(51) Int. Cl. H10B 61/00; G11C 5/06; H10N 50/01; H10N 50/10; H10N 50/80

(52) U.S. Cl. CPC H10B 61/10; G11C 5/063; H10N 50/01; H10N 50/10; H10N 50/80

(57) ABSTRACT

A method for fabricating a semiconductor device includes: forming a word line layer and a selector layer; etching the word line layer and the selector layer by using a first line-shaped mask extending in a first direction to form a word line and a selector line; etching the selector line by using a second line-shaped mask extending in a second direction intersecting with the first direction to form a selector pattern; forming an Magnetic Tunnel Junction (MTJ) layer; etching the MTJ layer by using a third line-shaped mask extending in a third direction that intersects with the second direction to form an MTJ line; forming a bit line layer; and etching the bit line layer and the MTJ line by using a fourth line-shaped mask extending in a fourth direction that intersects with the third direction to form a bit line and an MTJ pattern.

### CROSS-REFERENCE TO RELATED APPLICATIONS

The present application claims priority under 35 U.S.C 119(a) to Korean Patent Application No. 10-2024-0182369, filed on Dec. 10, 2024, which is incorporated herein by reference in its entirety.

### BACKGROUND

### 1. Field

Embodiments of the present disclosure relate to a semiconductor technology, and more particularly, to a semiconductor device including a variable resistance element and a selector, and a method for fabricating the semiconductor device.

### 2. Description of Related Art

Recent demands for miniaturization, low power consumption, high performance, and diversification of electronic devices require semiconductor devices capable of storing data in diverse electronic devices, such as computers, portable communication devices, and the like. Researchers and the industry are studying to develop semiconductor devices with these capabilities. An area of particular interest is the development of semiconductor devices capable of storing data based on using the characteristics of switching between different resistance states according to the applied voltage or current, such as a Resistive Random Access Memory (RRAM), a Phase-change Random Access Memory (PRAM), a Ferroelectric Random Access Memory (FRAM), a Magnetic Random Access Memory (MRAM), an E-fuse, and the like.

### SUMMARY

Embodiments of the present disclosure are directed to a semiconductor device that may reduce the difficulty and process complexity of a pillar patterning process through performing a four stage line patterning process that includes an etching process based on application of a line-shaped mask at each stage, reduce bridging that may be caused by the metal residue between cells during the pillar patterning process, secure isolation between a selector pattern and a Magnetic Tunnel Junction (MTJ) pattern, and achieve self-alignment between layers. Embodiments of the present disclosure further provide a method for fabricating the semiconductor device.

In accordance with an embodiment of the present disclosure, a semiconductor device includes: a plurality of word lines disposed over a substrate to extend in a first direction; a plurality of bit lines disposed over the plurality of word lines to extend in a second direction intersecting with the first direction; and a plurality of memory cells each coupled between the plurality of word lines and the plurality of bit lines and disposed at intersection areas of the plurality of word lines and the plurality of bit lines, wherein each of the memory cells includes a selector pattern and a Magnetic Tunnel Junction (MTJ) pattern disposed over the selector pattern, and the selector pattern is vertically aligned with the MTJ pattern.

In accordance with another embodiment of the present disclosure, a method for fabricating a semiconductor device includes: forming a word line layer and a selector layer over a substrate; etching the word line layer and the selector layer by using a first line-shaped mask extending in a first direction to form a word line and a selector line; etching the selector line by using a second line-shaped mask extending in a second direction intersecting with the first direction to form a selector pattern; forming an MTJ layer over a structure in which the selector pattern is formed; etching the MTJ layer by using a third line-shaped mask extending in a third direction that intersects with the second direction to form an MTJ line; forming a bit line layer over a structure in which the MTJ line is formed; and etching the bit line layer and the MTJ line by using a fourth line-shaped mask extending in a fourth direction that intersects with the third direction to form a bit line and an MTJ pattern.

### BRIEF DESCRIPTION OF THE DRAWINGS

FIG. 1A is a perspective view illustrating a semiconductor device according to a comparative example.

FIG. 1B is a top view illustrating the semiconductor device according to the comparative example.

FIG. 1C is a cross-sectional view illustrating the semiconductor device according to the comparative example.

FIGS. 2A to 2H illustrate a method for fabricating a semiconductor device in accordance with an embodiment of the present disclosure.

FIGS. 3A to 3D illustrate a semiconductor device in accordance with another embodiment of the present disclosure.

### DETAILED DESCRIPTION

Hereinafter, the diverse embodiments of the present disclosure will be described in detail with reference to the attached drawings.

Exemplary embodiments of the present disclosure will be described below in more detail with reference to the accompanying drawings. The present disclosure may, however, be embodied in different forms and should not be construed as limited to the embodiments set forth herein. Rather, these embodiments are provided so that this disclosure will be thorough and complete, and will fully convey the scope of the present disclosure to those skilled in the art. Throughout the disclosure, like reference numerals refer to like parts throughout the diverse figures and embodiments of the present disclosure.

The drawings are not necessarily to scale and in some instances, proportions may have been exaggerated in order to clearly illustrate features of the embodiments. When a first layer is referred to as being “on” a second layer or “on” a substrate, it not only refers to a case where the first layer is formed directly over the second layer or the substrate but also a case where a third layer exists between the first layer and the second layer or the substrate.

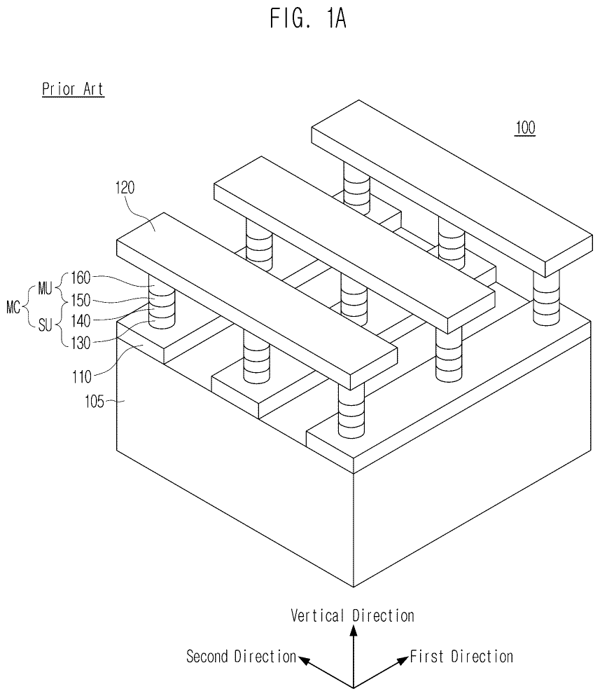

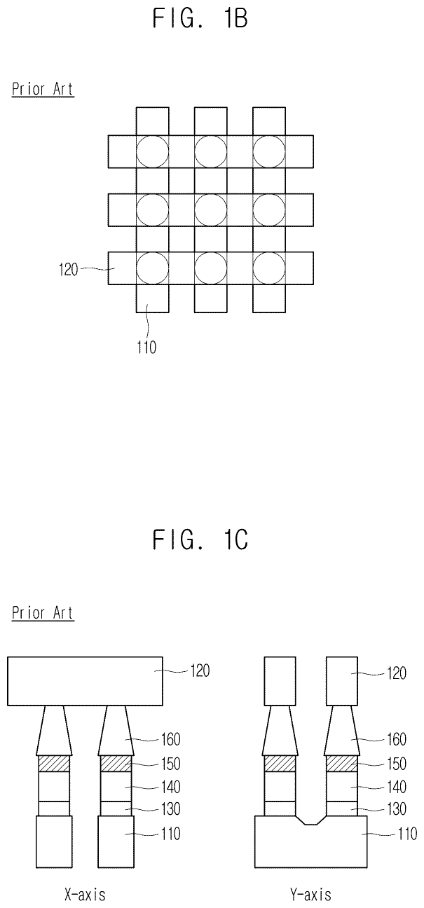

Referring to FIGS. 1A to 1C, a semiconductor device 100 according to a comparative example may include a substrate 105, a plurality of word lines 110 disposed over the substrate 105 and extending in a first direction, a plurality of bit lines 120 disposed over the word lines 110 and extending in a second direction intersecting with the first direction, and a plurality of memory cells MC, each of the memory cells MC being disposed to overlap each of the intersection areas between the word lines 110 and the bit lines 120. The first direction and the second direction may correspond to horizontal directions which are substantially parallel to the upper surface of the substrate 105 and may be substantially perpendicular to each other. A direction substantially perpendicular to the surface of the substrate 105 may be, hereinafter, referred to as a vertical direction. The substrate 105 may include a semiconductor material, such as silicon. Additionally, a required predetermined lower structure (not shown) may be formed in the substrate 105. For example, an integrated circuit for driving a word line 110 and/or a bit line 120 may be formed in the substrate 105.

Each of the memory cells MC may include a memory unit MU, which is a portion where data are stored, and a selector unit SU that controls access to the memory unit MU. For example, the memory cell MC may include a stacked structure of a selector layer 130, a first electrode layer 140, a second electrode layer 150, and a Magnetic Tunnel Junction (MTJ) layer 160.

The selector unit SU may include the selector layer 130, the first electrode layer 140, and the second electrode layer 150, and the memory unit MU may include the second electrode layer 150 and the MTJ layer 160. The second electrode layer 150 may be shared between the selector unit SU and the memory unit MU.

In contrast to processes provided in the present disclosure, which include a four-stage pillar patterning process, SC-MRAM formation according to other processes may include a pillar patterning process that requires repeated stacking of diverse hard masks HM, which causes a significant increase in the total number of processes. More particularly, these other processes may include performing each of a line patterning process and a pillar patterning process twice onto the word line 110, the selector layer 130, the MTJ layer 160, and the bit line 110 with the same design rule. As the number of processes is increased, there are concomitant increases in time and cost to fabricate the device, and the possibility of errors occurring due to process complexity increases. Additionally, these other processes may introduce or increase problems of misalignment of the lower layers in the pillar patterning process. The SC-MRAM may be formed of multiple layers, and precise alignment between the layers is very important. In these instances, small errors in the alignment process may have significant influence on the performance of the entire device, which may lead to serious problems, especially in high-density semiconductor devices. When patterning multiple layers of the SC-MRAM, especially a layer formed of a metal layer, metal residues may remain between the neighboring cells during the etching process. These residues may cause a bridge phenomenon, which creates an unintended (and performance deteriorating) electrical connection. More particularly, the bridge phenomenon may cause an electrical short. The bridge phenomenon is a major problem that increases the electrical interference between cells and reduces the reliability of a memory device.

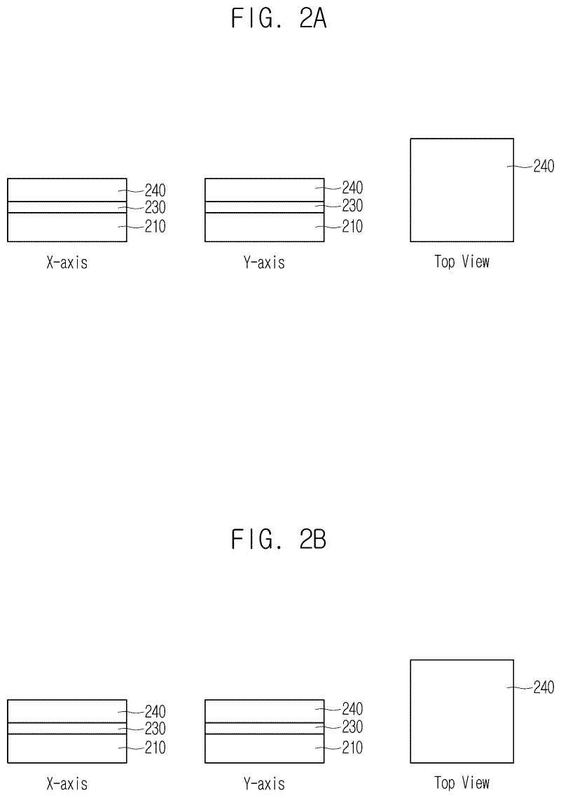

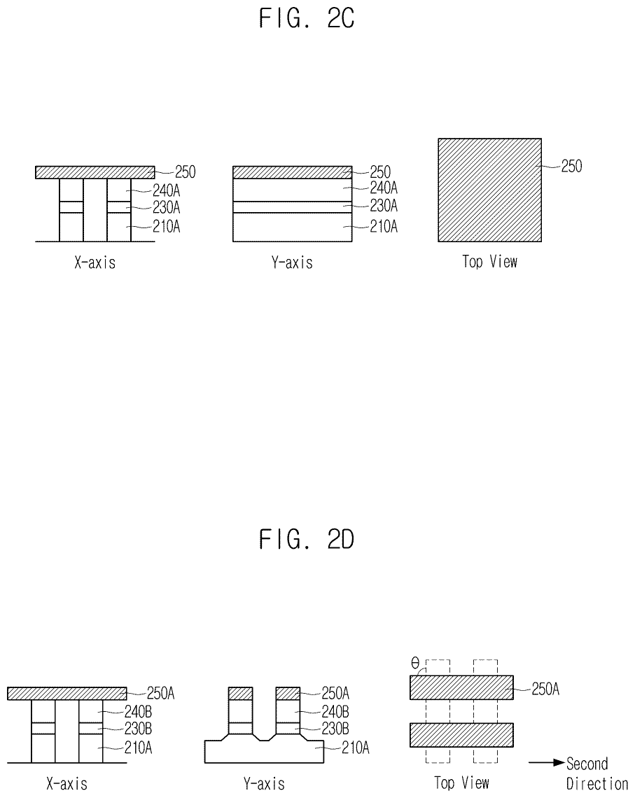

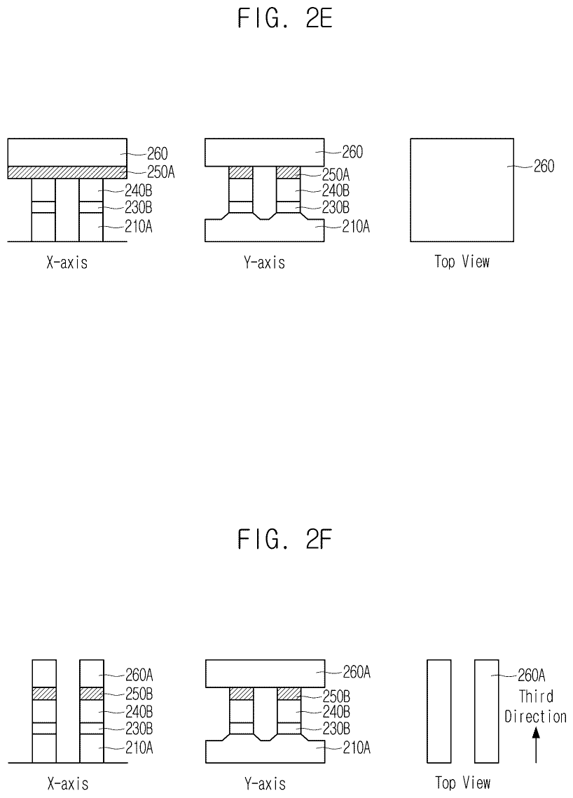

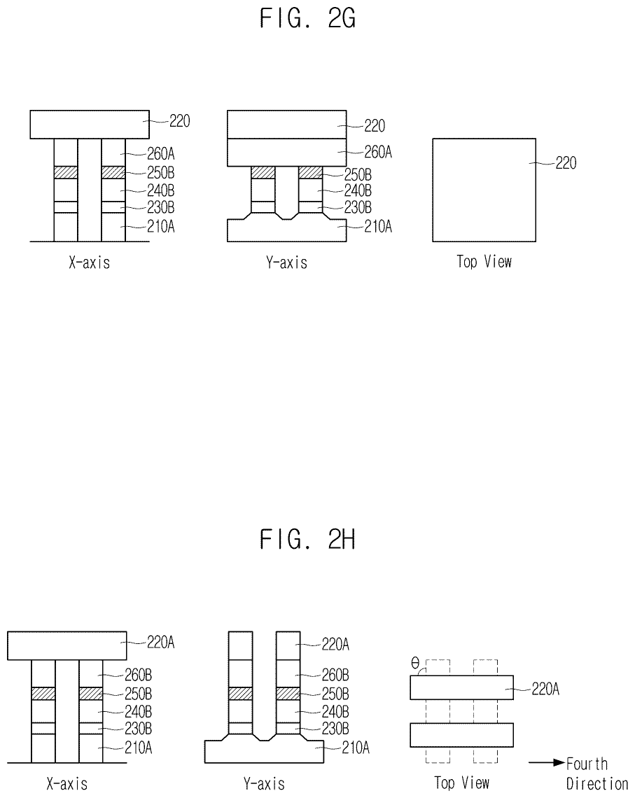

In accordance with embodiments of the present disclosure, a semiconductor device and a method for fabricating the same in accordance with an embodiment of the present disclosure may reduce the difficulty and process complexity of the pillar patterning process through a line patterning process that is performed four times (for example in four stages) by performing an etching process with a line-shaped mask (at each stage), improve the bridge problem caused by the metal residue between the neighboring cells during the pillar patterning process, secure isolation between the selector pattern and MTJ pattern (for example, selector pattern 230B and MTJ pattern 260B as described with respect to FIGS. 2A to 2H, herein below), and achieve self-alignment between the layers. Further, in accordance with the embodiment of the present disclosure, the semiconductor device and the fabrication method thereof may allow diverse arrangements and combinations of layers by diversely adjusting the patterning angle for each layer, and reducing the interference between cells by forming the word line 110 and the bit line 120 to be crossed with each other as described herein below with reference to FIGS. 2A to 2H.

FIGS. 2A to 2H illustrate a method for fabricating a semiconductor device in accordance with an embodiment of the present disclosure. FIGS. 2A to 2H each respectively illustrate a view from the perspective of the X-axis, a view from the perspective of the Y-axis, and a top view from an overhead perspective (for example, a Z-axis, not shown in FIGS. 2A to 2H) during the fabrication process of the present disclosure. The fabrication process of the present disclosure may form two lines, which are the word line and the bit line, and two pillar-shaped patterns, which are a selector pattern and a Magnetic Tunnel Junction (MTJ) pattern, by presenting a total of five layers and performing only the line patterning process four times. The process efficiency for fabricating a semiconductor device may be greatly improved through embodiments of the present disclosure since the line patterning process has a lower process difficulty than the pillar patterning process and the upper layer may be utilized as a hard mask HM.

Referring to FIG. 2A, a selector layer 230 may be formed in the upper portion of a word line layer 210, and a first electrode layer 240 may be formed in the upper portion of the selector layer 230.

The word line layer 210 may be formed by forming a gap-fill layer (not shown) having a trench for forming the word line layer 210 over a predetermined structure, and depositing a conductive layer for forming the word line layer 210 in the trench. The word line layer 210 may include diverse conductive materials, for example, metals such as platinum (Pt), tungsten (W), aluminum (Al), copper (Cu), tantalum (Ta) and the like, metal nitrides such as titanium nitride (TiN), tantalum nitride (TaN) and the like, or a combination thereof. The word line layer 210 may have a single-layer structure or a multi-layer structure. The lower portion of the word line layer 210 may include a metallic material, and the upper portion of the word line layer 210 may include carbon or a carbon-based material. A metallic material layer may be formed over a substrate by depositing a metal material such as tungsten (W), titanium nitride (TiN), titanium (Ti), aluminum (Al), tantalum (Ta), cobalt (Co) by a method such as sputtering or Chemical Vapor Deposition (CVD). After the metallic material layer is formed, the adhesion of a carbon-based thin layer to be deposited thereon may be increased, and the surface may be activated by performing a plasma treatment to remove impurities and planarize the surface, or surface contaminants may be removed by a wet cleaning process. A carbon-based thin layer including carbon or a carbon-based material, such as graphite, carbon nanotube, graphene, doped carbon, or amorphous carbon, may be deposited over the metallic material layer by a Chemical Vapor Deposition (CVD) process, a Physical Vapor Deposition (PVD) process, or an Atomic Layer Deposition (ALD) process.

The selector layer 230 may include an OTS (Ovonic Threshold Switching) material such as a diode, a chalcogenide-based material and the like, an MIEC (Mixed Ionic Electronic Conducting) material such as a metal-containing chalcogenide-based material and the like, an MIT (Metal-Insulator-Transition) material such as NbO₂, VO₂ and the like, or a tunneling dielectric material having a relatively wide band gap such as SiO₂, Al₂O₃, and the like.

The selector layer 230 may also include a dielectric material that is doped with a dopant. In these instances, the dielectric material may include a silicon-containing dielectric material such as silicon oxide, silicon nitride, silicon oxynitride and the like, a dielectric metal oxide, a dielectric metal nitride, or a combination thereof. The dopant may function to capture a conductive carrier migrating within the dielectric material or to create a trap site that provides a path through which the captured conductive carrier migrates again. In the instances in which a trap site is formed, the dopant may be selected from a diverse group of elements that may generate an energy potential capable of accommodating a conductive carrier in the dielectric material. For example, when the dielectric material contains silicon, the dopant may include a metal having a different valence from the valence of silicon, such as gallium (Ga), boron (B), indium (In), phosphorus (P), arsenic (As), antimony (Sb), germanium (Ge), carbon (C), tungsten (W), or a combination thereof. Also, when the dielectric material contains a metal, the dopant may include a metal having a different valence from the valence of the metal, such as silicon. For example, the selector layer 230 may include silicon dioxide (SiO₂) that is doped with arsenic (As) or germanium (Ge). When a voltage which is equal to or higher than the threshold voltage is applied to the selector layer 230 including a dielectric material that is doped with a dopant, an on-state in which a current flows through the selector layer 230 may be realized as the conductive carrier migrates through the trap site, and when the voltage applied to the selector layer 230 is decreased to be lower than the threshold voltage, an off-state in which the current does not flow because the conductive carrier does not migrate may be realized.

The first electrode layer 240 may include diverse conductive materials, for example, a metal such as platinum (Pt), tungsten (W), aluminum (Al), copper (Cu), tantalum (Ta), molybdenum (Mo), titanium (Ti), and the like, a metal nitride such as titanium nitride (TiN), tantalum nitride (TaN), and the like, or a combination thereof. Also, the first electrode layer 240 may include a carbon electrode.

In order to prevent the upper portion of the selector layer 230 from directly contacting the metal included in the first electrode layer 240, a carbon-based thin layer containing carbon or a carbon-based material, such as graphite, carbon nanotube, graphene, doped carbon, or amorphous carbon, may be deposited in the upper portion of the selector layer 230 by a Chemical Vapor Deposition (CVD) process, a Physical Vapor Deposition (PVD) process, or an Atomic Layer Deposition (ALD) process. The carbon-based thin layer may function as a physical and/or chemical barrier between the selector pattern (230B of FIG. 2H) and the first electrode pattern (240B of FIG. 2H), which are to be formed later, thereby suppressing reaction or diffusion between the metals included in the selector pattern 230B and the first electrode pattern 240B.

Referring to FIG. 2B, the word line layer 210, the selector layer 230, and the first electrode layer 240 may be etched by using a first line-shaped mask extending in the first direction to form a word line 210A, a selector line 230A, and a first electrode line 240A. This process may be performed through a lithography process, an etching process, and an etching residue removal process. First, a photoresist may be applied to the upper portions of the selector layer 230 and the first electrode layer 240 and exposed to light through the first line-shaped mask to form a line pattern. The first line-shaped mask may be a mask having a line pattern extending in a particular direction, and light may be projected onto the photoresist through this mask. The photoresist may be exposed to light, as the light passes through a transparent portion of the mask.

After the light exposure process is completed, when the photoresist is removed with a chemical solution along the exposed portion and the unexposed portion, only a portion of the remaining photoresist corresponding to the first line-shaped mask pattern may remain after development. The word line layer 210, the selector layer 230, and the first electrode layer 240 may be etched by an etching process using this first line-shaped mask pattern. The etching process may be a dry etching process using plasma or an ion beam or a wet etching process of selectively etching a particular material by using a chemical solution. After the etching process is completed, the remaining photoresist may be removed through a plasma etching process or a chemical stripping process to form the word line 210A, the selector line 230A, and the first electrode line 240A. A cleaning process may be performed to remove the residue after the etching process. Through this process, each layer may be precisely patterned and the alignment between the layers may be improved.

Referring to FIG. 2C, a second electrode layer 250 may be formed over the first electrode line 240A. The second electrode layer 250 may include diverse conductive materials, for example, metals such as platinum (Pt), ruthenium (Ru), cobalt (Co), nickel (Ni), iridium (Ir), tungsten (W), aluminum (Al), copper (Cu), tantalum (Ta), titanium (Ti) and the like, metal nitrides such as titanium nitride (TiN), tantalum nitride (TaN) and the like, or a combination thereof. Also, the second electrode layer 250 may include a carbon electrode. The first electrode layer 240 and the second electrode layer 250 may have the same thickness or may have different thicknesses.

Referring to FIG. 2D, the selector line 230A and the first electrode line 240A may be etched by using a second line-shaped mask extending in the second direction that intersects with the first direction to form a pillar-shaped selector pattern 230B and a pillar-shaped first electrode pattern 240B, and at the same time, to form a second electrode line 250A. The formed first electrode pattern 240B may be electrically connected to the selector pattern 230B, and may have a function of electrically connecting the selector pattern 230B and the MTJ pattern (260B in FIG. 2H) while physically separating them from each other. The selector pattern 230B may have a function of preventing a current leakage that may occur between the memory cells MC that share the word line 210A or the bit line 220A while controlling the access to the MTJ pattern 260B. To this end, the selector pattern 230B may have the threshold switching characteristics of blocking off the current or holding the current to negligible (or substantially decreased) flow when the level of the voltage supplied to the upper and lower ends of the selector pattern 230B is lower than a predetermined threshold voltage level, and letting the current rapidly flow when the level of the voltage supplied to the upper and lower ends of the selector pattern 230B is at a voltage level which is equal to or higher than the threshold voltage level. In other words, the selector pattern 230B may be turned on at a voltage level which is equal to or higher than the threshold voltage level and turned off at a voltage level which is lower than the threshold voltage level.

The process of forming the selector pattern 230B and the first electrode pattern 240B may include a lithography process and an etching process. For example, this process may be performed by forming a desired pattern through a lithography process and then removing material through an etching process to form a desired pillar shape corresponding to the selector pattern 230B and the first electrode pattern 240B. The patterning using the second line-shaped mask may be performed by forming a cross pattern with a line structure extending in the first direction and performing the same process as the line patterning process using the first line-shaped mask. This helps increase the process efficiency and ensure precise alignment between the layers. In other words, since multiple layers may be patterned in one process, the process efficiency may be greatly increased. This method may minimize the alignment error of each layer and secure the consistency of the etching process.

The selector pattern 230B and the first electrode pattern 240B having a pillar structure may be formed by performing a line patterning process two times, that is, a line patterning process using the first line-shaped mask of FIG. 2B and a line patterning process using the second line-shaped mask of FIG. 2D. This pillar structure may ensure an independent electrical path between a selector and an electrode, thereby contributing to improving the reliability of the semiconductor device.

The angle (θ) between the second direction in which the second electrode line 250A extends and the first direction in which the word line 210A extends may be set in the range of approximately 30° to 150°, and in instances where beneficial, the angle (θ) may be set to approximately 90°. This angle may be optimized according to the arrangement and structure of the device, and it is possible to prevent cross-interference while ensuring the optimal electrical connection between the layers by controlling the patterning at a predetermined angle.

Referring to FIG. 2E, an MTJ layer 260 may be formed over the second electrode line 250A. The MTJ layer 260 may have a single-layer structure or a multi-layer structure including diverse materials used in a Resistive Random Access Memory (RRAM), a Phase-change Random Access Memory (PRAM), a Ferroelectric Random Access Memory (FRAM), a Magnetic Random Access Memory (MRAM) and the like, for example, metal oxides such as transition metal oxides, perovskite-based materials and the like, phase-change materials such as chalcogenide-based materials and the like, ferroelectric materials, ferromagnetic materials, and the like.

Referring to FIG. 2F, the second electrode line 250A and the MTJ layer 260 may be etched by using a third line-shaped mask extending in a third direction that intersects with the second direction to form a pillar-shaped second electrode pattern 250B and a pillar-shaped Magnetic Tunnel Junction (MTJ) line 260A. The formed second electrode pattern 250B may be electrically connected to the MTJ pattern (260B of FIG. 2H), and may function to electrically connect the selector pattern 230B and the MTJ pattern 260B while physically separating them from each other. The patterning process using the third line-shaped mask may be performed by forming a cross-pattern with a line structure extending in the second direction and performing the same process as the line patterning process using the first and second line-shaped masks. The angle between the second direction and the third direction may be set in the range of approximately 30° to 150°, and, in beneficial instances, may be set to approximately 90°.

In this process, the second electrode pattern 250B may be transformed into a pillar structure, and the MTJ layer 260 may be patterned into a line structure. The MTJ line 260A may have a function of providing an electrical path independently from the selector pattern 230B and the first electrode pattern 240B. As a result, it is possible to form an electrical path that allows each layer of the device to operate efficiently while maintaining an independent function.

The third line-shaped mask may intersect with the pattern extending in the second direction to form a pattern extending in the third direction. This may allow each layer inside the device to have a cross-arrangement, thereby securing alignment between the upper and lower layers and preventing electrical interference. This cross-arrangement may optimize the circuit structure of the entire device by crossing the line structures that are formed in the first and second directions. In the above process, the patterning process using the first, second, and third line-shaped masks may allow each layer of the device to have a precise cross-arrangement, thereby minimizing alignment errors.

Referring to FIG. 2G, a bit line layer 220 may be formed over the MTJ line 260A. The bit line layer 220 may be formed by forming a trench for forming the bit line layer 220 and then depositing a conductive layer for forming the bit line layer 220 in the trench. The bit line layer 220 may include diverse conductive materials, for example, metals such as platinum (Pt), tungsten (W), aluminum (Al), copper (Cu), tantalum (Ta), and the like, metal nitrides such as titanium nitride (TiN), tantalum nitride (TaN), and the like, or a combination thereof, and the bit line layer 220 may have a single-layer structure or a multi-layer structure.

Referring to FIG. 2H, the bit line layer 220 and the MTJ line 260A may be etched by using a fourth line-shaped mask extending in a fourth direction that intersects with the third direction to form a bit line 220A and a pillar-shaped MTJ pattern 260B. The MTJ pattern 260B may be a portion that functions to store data in the memory cell MC. To this end, the MTJ pattern 260B may have the variable resistance characteristics of switching between different resistance states according to the applied voltage.

The MTJ pattern 260B may include a free layer, a tunnel barrier layer, and a fixed layer. The free layer may be a layer that may store different data by having a changeable magnetization direction, and the MTJ pattern 260B may also be called a storage layer. The fixed layer may be a layer that may be contrasted with the magnetization direction of the free layer by having a fixed magnetization direction, and the fixed layer may also be called a reference layer. Each of the free layer and the fixed layer may have a magnetization direction which is substantially parallel to the vertical direction or a magnetization direction which is substantially parallel to the horizontal direction. The tunnel barrier layer may physically separate the fixed layer and the free layer from each other while enabling tunneling of electrons between them.

The MTJ pattern 260B may store different data by switching between different resistance states according to the applied voltage or current. To be more specific, when the magnetization direction of the free layer varies according to the voltage or current applied to the MTJ pattern 260B and becomes parallel to the magnetization direction of the fixed layer, the MTJ pattern 260B may have a low resistance state and may store, for example, data ‘1’. On the other hand, when the magnetization direction of the free layer varies according to the voltage or current applied to the MTJ pattern 260B and becomes anti-parallel to the magnetization direction of the fixed layer, the MTJ pattern 260B may have a high resistance state and may store, for example, data ‘0’. According to the present embodiment of the present disclosure, the magnetization direction of the free layer of the MTJ pattern 260B may vary according to the voltage or current applied thereto.

In the MTJ pattern 260B, each of the free layer and the fixed layer may independently have a single-layer structure or a multi-layer structure including a ferromagnetic material. For example, each of the free layer and the fixed layer may independently include at least one among alloys mainly formed of Fe, Ni or Co, such as an Fe—Pt alloy, an Fe—Pd alloy, a Co—Pd alloy, a Co—Pt alloy, a Fe—Ni—Pt alloy, a Co—Fe—Pt alloy, a Co—Ni—Pt alloy, an Fe—Pd alloy, and a Co—Fe—B alloy, or may include at least one among a Co/Pt stacked structure and a Co/Pd stacked structure. The tunnel barrier layer may have a single-layer or multi-layer structure including a dielectric material. For example, the tunnel barrier layer may include a dielectric oxide such as MgO, CaO, SrO, TiO, VO, NbO, and the like.

This process may be performed in the same manner by applying the lithography process and the etching process described earlier. A pattern may be formed in the area where the bit line 220A and the MTJ pattern 260B are to be formed by applying a photoresist onto the upper portions of the bit line layer 220 and the MTJ layer 260, and performing exposure and development processes by using the fourth line-shaped mask. Subsequently, the bit line 220A and the MTJ pattern 260B may be formed vertically by removing the bit line layer 220 and the MTJ line 260A through a plasma etching process.

The line structure extending in the third direction and the line structure extending in the fourth direction may intersect with each other, and the angle (θ) between these two directions may be adjusted in the range of approximately 30° to 150°. In particular, selected angle may be set to approximately 90° to optimize the pattern efficiency of the semiconductor device. This cross pattern may minimize the interference between the selector pattern 230B, the word line 210A, and the bit line 220A, and the cross pattern may be appropriate for fabricating a highly integrated semiconductor device.

According to the embodiment of the present disclosure, the sidewall of the formed selector pattern 230B and the sidewall of the formed MTJ pattern 260B may be self-aligned (for example, based on the application of the line-shaped masks in cross-arrangement to secure alignment between the layers of the device). As a result, it is possible to improve the operation reliability of the device by minimizing the (for example, electrical)_interference between the pillars and to fabricate a high-precision device by reducing the imbalance or alignment errors that may occur during the formation of the pattern. Since the sidewalls of the pillars are precisely aligned, the electrical interference between the upper and lower structures may be minimized, and the performance of the device may be optimized.

According to the embodiment of the present disclosure, the word line 210A, the selector pattern 230B, the first electrode pattern 240B, the second electrode pattern 250B, the MTJ pattern 260B, and the bit line 220A may be formed through a line patterning process that is performed (only) four times, thereby greatly improving the fabrication efficiency of the device. Each process for forming the pattern may be consistently performed through a lithography process and a plasma etching process, and the alignment state of each layer may be reliably maintained. In particular, the angle between the third direction and the fourth direction may be selected in the range of approximately 30° to 150°. Therefore, it may be optimized for diverse device designs.

Since the method for fabricating a semiconductor device in accordance with this embodiment of the present disclosure may be able to solve the process difficulty and the cost problem that may occur in the existing patterning method, it is possible to fabricate a more efficient and precise device.

Through the above process, a semiconductor device in accordance with the embodiment of the present disclosure may be formed. Referring back to FIG. 2H, the semiconductor device may have a structure in which the word line 210A, the selector pattern 230B, the first electrode pattern 240B, the second electrode pattern 250B, the MTJ pattern 260B, and the bit line 220A are sequentially stacked in accordance with the embodiment of the present disclosure. The semiconductor device may include the selector pattern 230B, the first electrode pattern 240B, the second electrode pattern 250B, and the MTJ pattern 260B that are disposed to overlap with the intersection area between the word line 210A and the bit line 220A in the first direction. The selector pattern 230B, the first electrode pattern 240B, the second electrode pattern 250B, and the MTJ pattern 260B may be self-aligned to minimize the alignment errors of each layer. Also, the layer structure of the memory cell MC may not be limited to what is illustrated, and one or more among the layers may be omitted, or one or more layers may be added. For example, one or more layers among the first electrode pattern 240B and the second electrode pattern 250B may be omitted. Also, one or more layers (not shown) may be added to the memory cell MC to improve the process or the characteristics of the memory cell MC.

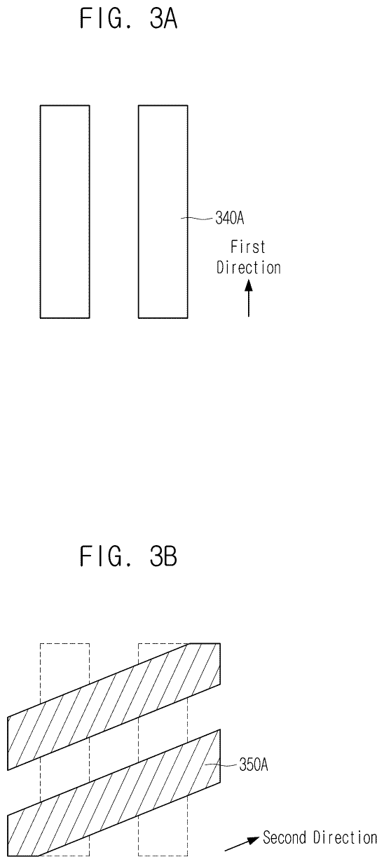

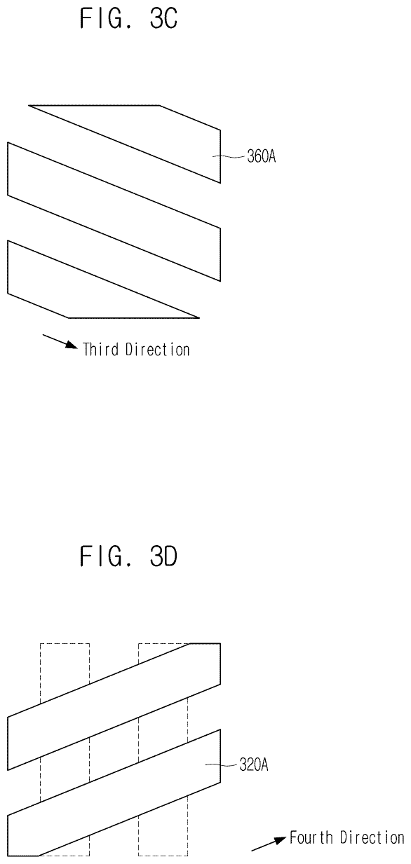

FIGS. 3A to 3D illustrate a semiconductor device in accordance with another embodiment of the present disclosure.

The line patterning process of FIGS. 3A to 3D that is performed four times may correspond to the line patterning process of FIGS. 2B, 2D, 2F, and 2H that is performed four times, respectively, and detailed descriptions on the portions of the process that are similar to those disclosed with respect to the illustrated embodiment of FIGS. 2B, 2D, 2F, and 2H will be omitted.

Referring to FIG. 3A, a stacked structure in which the word line layer, the selector layer, and the first electrode layer are stacked may be etched by using the first line-shaped mask extending in the first direction to form a stacked structure in which a word line, a selector line, and a first electrode line 340A are stacked.

Referring to FIG. 3B, a stacked structure in which the word line, the selector line, the first electrode line, and the second electrode layer are stacked may be etched by using the second line-shaped mask extending in the second direction that intersects with the first direction so as to form a stacked structure in which a word line, a selector pattern, a first electrode pattern, and a second electrode line 350A are stacked. Here, the angle (θ) between the first direction and the second direction may be set in the range of approximately 30° to 150° (for example, at 90°).

Referring to FIG. 3C, a stacked structure in which the word line, the selector pattern, the first electrode pattern, the second electrode line, and the MTJ layer are stacked may be etched by using the third line-shaped mask extending in the third direction that intersects with the second direction so as to form a stacked structure in which a word line, a selector pattern, a first electrode pattern, a second electrode pattern, and an MTJ line 360A are stacked. Here, the angle (θ) between the second direction and the third direction may be set in the range of approximately 30° to 150°.

Referring to FIG. 3D, the stacked structure in which the word line, the selector pattern, the first electrode pattern, the second electrode pattern, the MTJ line, and the bit line layer are stacked may be etched by using the fourth line-shaped mask extending in the fourth direction that intersects with the third direction so as to form a stacked structure in which a word line, a selector pattern, a first electrode pattern, a second electrode pattern, an MTJ pattern, and a bit line 320A are stacked. Here, the angle (θ) between the third direction and the fourth direction may be set in the range of approximately 30° to 150°.

According to this embodiment of the present disclosure, the patterning process for each line may not be simply performed only at approximately 90° intervals, but may be performed by flexibly adjusting the angle in the range of approximately 30° to 150°. By applying the line patterning at diverse angles, the electrical isolation between the layers may be enhanced, preventing such problems as electrical leakage from occurring, and the degree of freedom in design may be increased because the angle may be adjusted, and the patterning may be controlled according to the diverse circuit configurations and arrangements. This may increase the integration degree of the device and improve the overall performance.

Also, since it may be set at diverse angles compared to the existing patterning method of the 90° interval, the process may be performed more simply while minimizing the interference between the layers. This may reduce the complexity of the fabrication process, reduce the fabrication costs, and contribute to increasing the productivity. Through this patterning process, a pattern may be formed in such a manner that each layer is self-aligned. In particular, the sidewalls of the selector pattern and the MTJ pattern may be automatically aligned, enabling precise arrangement between the layers and minimizing alignment errors between the layers. Thus, a sidewall of the selector pattern may be vertically aligned with a sidewall of the MTJ pattern, ensuring that the current path between the two elements is minimized and consistent across memory cells. Such vertical alignment contributes to improved electrical performance, reduced parasitic resistance, and enhanced scalability of the device in highly integrated memory architectures.

According to an embodiment of the present disclosure, a semiconductor device and a method for fabricating the same may reduce the difficulty and process complexity of a pillar patterning process, improve a bridge problem that may be caused due to the metal residue between the neighboring cells during the pillar patterning process, secure isolation between the selector pattern and the MTJ pattern, and achieve self-alignment between layers.

Also, according to the embodiment of the present disclosure, the semiconductor device and the method for fabricating the same may allow diverse arrangements and combinations of layers by diversely adjusting the patterning angle for each layer, and reducing the interference between cells by forming the word lines and the bit lines to be crossed with each other.

While the present disclosure has been described with respect to the specific embodiments, it will be apparent to those skilled in the art that diverse changes and modifications may be made without departing from the spirit and scope of the invention as defined in the following claims.

What is claimed is:

1. A semiconductor device comprising:
a plurality of word lines disposed over a substrate to extend in a first direction;
a plurality of bit lines disposed over the plurality of word lines to extend in a second direction intersecting with the first direction; and
a plurality of memory cells each coupled between the plurality of word lines and the plurality of bit lines and disposed at intersection areas of the plurality of word lines and the plurality of bit lines,
wherein each of the memory cells includes a selector pattern, and a Magnetic Tunnel Junction (MTJ) pattern disposed over the selector pattern, and
a sidewall of the selector pattern is vertically aligned with a sidewall of the MTJ pattern.

2. The semiconductor device of claim 1, further comprising a first electrode layer disposed over the selector pattern.

3. The semiconductor device of claim 2, wherein the first electrode layer includes one or more of tungsten (W), titanium nitride (TiN), tantalum (Ta), molybdenum (Mo), and copper (Cu).

4. The semiconductor device of claim 1, further comprising a second electrode layer disposed below the MTJ pattern.

5. The semiconductor device of claim 4, wherein the second electrode layer includes one or more of platinum (Pt), ruthenium (Ru), cobalt (Co), nickel (Ni), and iridium (Ir).

6. The semiconductor device of claim 1, wherein an angle between the first direction and the second direction ranges from 30° to 150°.

7. The semiconductor device of claim 1, wherein the second direction is perpendicular to the first direction.

8. The semiconductor device of claim 1, wherein each of the plurality of word lines includes an upper portion with a carbon-based conductive thin layer.

9. The semiconductor device of claim 1, wherein the selector pattern includes an upper portion with a carbon-based conductive thin layer.

10. A method for fabricating a semiconductor device, the method comprising:
forming a word line layer and a selector layer over a substrate;
etching the word line layer and the selector layer by using a first line-shaped mask extending in a first direction to form a word line and a selector line;
etching the selector line by using a second line-shaped mask extending in a second direction that intersects with the first direction to form a selector pattern;
forming an MTJ layer over a structure in which the selector pattern is formed;
etching the MTJ layer by using a third line-shaped mask extending in a third direction that intersects with the second direction to form an MTJ line;
forming a bit line layer over a structure in which the MTJ line is formed; and
etching the bit line layer and the MTJ line by using a fourth line-shaped mask extending in a fourth direction that intersects with the third direction to form a bit line and an MTJ pattern.

11. The method of claim 10, further comprising:
forming a first electrode layer over the selector layer;
etching the first electrode layer by using the first line-shaped mask to form a first electrode line; and
etching first electrode line by using the second line-shaped mask to form a first electrode pattern over the selector pattern.

12. The method of claim 11, wherein the first electrode layer includes one or more of tungsten (W), titanium nitride (TiN), tantalum (Ta), molybdenum (Mo), or copper (Cu).

13. The method of claim 11, further comprising:
forming a second electrode layer over a structure in which the first electrode line is formed; and
etching by using the second line-shaped mask to form a second electrode line over the first electrode pattern.

14. The method of claim 13, wherein the second electrode layer includes one or more of platinum (Pt), ruthenium (Ru), cobalt (Co), nickel (Ni), and iridium (Ir).

15. The method of claim 10, wherein an angle between the first direction and the second direction ranges from 30° to 150°.

16. The method of claim 10, wherein the second direction is perpendicular to the first direction.

17. The method of claim 10, wherein a sidewall of the formed selector pattern and a sidewall of the formed MTJ pattern are self-aligned.

18. The method of claim 10, wherein an angle between the second direction and the third direction ranges from 30° to 150°.

19. The method of claim 10, wherein an angle between the third direction and the fourth direction ranges from 30° to 150°.

20. The method of claim 10, wherein the fourth direction is perpendicular to the first direction.
